(19) United States
(12) Patent Application Publication
(10) Pub. No.: US 2010/0099258 A1
(43) Pub. Date: Apr. 22, 2010

(54) SEMICONDUCTOR DEVICE CLEANING METHOD AND SEMICONDUCTOR DEVICE MANUFACTURING METHOD USING THE SAME

(76) Inventor: Yong-Su Hoh, Gangnam-gu (KR)

Correspondence Address: SHERR & VAUGHN, PLLC, 620 HERNDON PARKWAY, SUITE 320, HERNDON, VA, 20170, US

(21) Appl. No.: 12/577,069

(22) Filed: Oct. 9, 2009

(30) Foreign Application Priority Data
Oct. 17, 2008 (KR) 10-2008-0101841

(51) Int. Cl. H01L 21/306

(52) U.S. Cl. 438/689; 257/E21.215; 257/E21.228

(57) ABSTRACT

A semiconductor device cleaning method includes etching one of a semiconductor substrate for forming a contact hole in the semiconductor substrate and the bottom of the contact hole on a semiconductor substrate, and cleaning the semiconductor substrate with a cleaning solution, wherein the cleaning solution includes a mixture of sulfuric acid (H₂SO₄), hydrogen peroxide (H₂O₂) and hydrogen fluoride (HF). Cleaning the semiconductor substrate may include clamping the semiconductor substrate on a spin chuck, cleaning the semiconductor substrate by spraying the semiconductor substrate with the cleaning solution while spinning the semiconductor substrate using the spin chuck, spraying and rinsing the semiconductor substrate with deionized water while spinning the semiconductor substrate, and drying the semiconductor substrate by continuing to spin the semiconductor substrate.

The present application claims priority under 35 U.S.C. 119 to Korean Patent Application No. 10-2008-0101841 (filed on Oct. 17, 2008), which is hereby incorporated by reference in its entirety.

### BACKGROUND

Among the elements of a semiconductor device, a metal contact is used to connect lower conductive patterns such as gate and source/drain regions to metal lines. To form such a metal contact, a hole etching process is used to form holes by etching a dielectric layer between gates, and then gap-filling a conductive material into the holes.

A BPSG film may be used as the dielectric layer. After completing the hole etching process for the BPSG film, cleaning process using a SH (Sulfuric Hydroxide) is performed to remove a photoresist used as a mask and a polymer which is a residual product generated by etching.

Hereinafter, a related method for manufacturing a metal contact of a semiconductor device will be described in detail. First, a barrier film and a dielectric layer are sequentially formed on a semiconductor substrate on which a lower metal (conductive) pattern such as a gate and a source/drain region has been formed. A contact hole is formed by selectively etching the dielectric layer. After forming the contact hole, a first cleaning process is performed to remove a photoresist and polymer which have been produced by the etching process.

After the first cleaning process, the semiconductor substrate is subjected to an annealing process. The barrier film exposed by the contact hole is subjected to an etching process so that the lower metal pattern is opened. A second cleaning process is then performed on a bottom of the contact hole to remove a photoresist and polymer which have been produced by the etching process, i.e., the selective etching process for the barrier film After the second cleaning process, a liner barrier metal is formed on an inner side of the contact hole. Finally the contact hole is filled with metal to form a metal contact.

In the first and second cleaning processes, a predetermined number of semiconductor substrates are subjected to SPM (Surfuric acid Peroxide Mixture) treatment using a SPM bath and then HQDR (Hot Quick Dump Rinse) treatment using a HQDR bath in order to remove chemicals on the semiconductor substrates. Finally the substrates are subjected to APR (ammonium peroxide replacement) treatment using an APR bath and then a drying treatment.

If a BPSG film is used as the dielectric layer, there may occur an abnormality in concentration of boron. The boron is released from the BPSG film during the annealing process and is removed by NC₂ chemical treatment of the APR bath in the first and second cleaning process. The NC₂ chemical treatment is carried out at a temperature in a range from 55° C. to 75° C. using a mixture solution of alkaline chemicals, peroxide (H₂O₂) and hot deionized water (DIW).

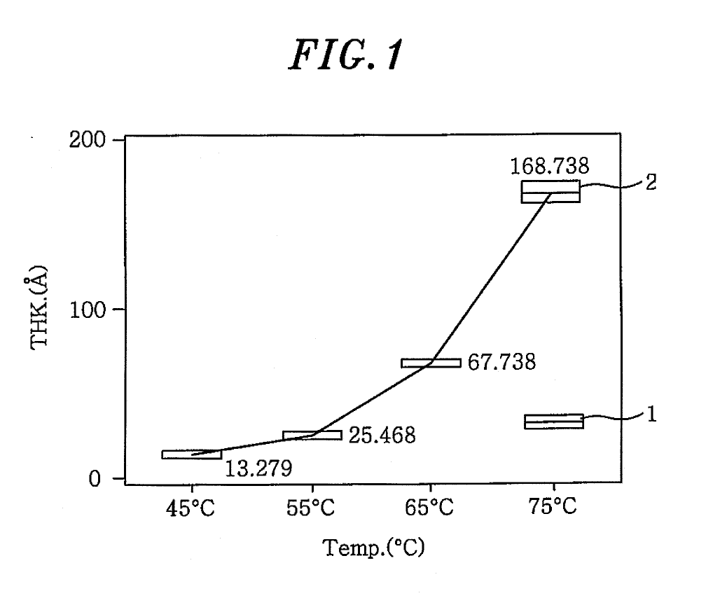

As described above, the related method for manufacturing the semiconductor device performs the NC₂ cleaning process to remove boron released from the BPSG film which is the dielectric layer. In this case, as shown in Example FIG. 1, under normal conditions at a temperature of 75° C., while an etching rate is about 35 Å/min. for a normal BPSG film 10, it is about 168 Å/min for an abnormal BPSG film 20 having an abnormal concentration. Accordingly, the abnormal BPSG film has an inferior contact profile due to its high etching rate.

In addition, even when the temperature condition of the NC₂ cleaning process is set at 55° C. in order to alleviate the above problem, a process margin is insufficient so that it is difficult to maintain the predetermined temperature condition. If the temperature is further increased to maintain the predetermined temperature condition, this may change a size of the contact hole due to excessive etching of the BPSG film, which may result in a change in electrical characteristics of the contact, such as the R-C (resistance-capacitive) characteristics, and the like.

### SUMMARY

Embodiments relate to a semiconductor device cleaning method for effectively removing residual products and the like, which are generated after performing an etching process for forming contact holes, preventing a dielectric layer from being excessively etched, and preventing a contact profile from being deteriorated. Embodiments relate to a semiconductor device manufacturing method using the semiconductor device cleaning method.

In a view of the above, embodiments relate to a semiconductor device cleaning method and a semiconductor device manufacturing method to effectively remove by-products, residual photoresist or polymer, and the like, which are produced after performing an etching process for forming contact holes or after etching the bottom of contact holes. Further, embodiments relate to a semiconductor device cleaning method and a semiconductor device manufacturing method which prevent a BPSG film as a dielectric layer from being excessively etched, and preventing an inferior contact profile resulting from a cleaning process even if the BPSG film is abnormal due to an abnormal boron concentration.

Embodiments relate to a semiconductor device cleaning method which includes: etching one of a semiconductor substrate for forming a contact hole in the semiconductor substrate and the bottom of the contact hole on a semiconductor substrate, and cleaning the semiconductor substrate with a cleaning solution, wherein the cleaning solution includes a mixture of sulfuric acid (H₂SO₄), hydrogen peroxide (H₂O₂) and hydrogen fluoride (HF).

Embodiments relate to a semiconductor device manufacturing method including: forming a contact hole on a semiconductor substrate where a barrier film and a dielectric layer are sequentially formed over a lower metal pattern by selectively etching a portion of the dielectric layer, thereby exposing a portion of the barrier film; performing a first cleaning for cleaning the semiconductor substrate on which the contact hole is formed; annealing the semiconductor substrate; opening the lower metal pattern by etching the portion of the barrier film exposed by the contact hole; and performing a second cleaning for cleaning the semiconductor substrate, wherein said performing a first cleaning includes cleaning the semiconductor substrate with a cleaning solution which is a mixture of sulfuric acid (H₂SO₄), hydrogen peroxide (H₂O₂) and hydrogen fluoride (HF).

Embodiments relate to a semiconductor device manufacturing method including: forming a contact hole on a semiconductor substrate where a barrier film and a dielectric layer are sequentially formed on a lower metal pattern, by selectively etching a portion of the dielectric layer, thereby exposing a portion of the barrier film; performing a first cleaning for cleaning the semiconductor substrate on which the contact hole is formed; annealing the semiconductor substrate; opening the lower metal pattern by etching the portion of the barrier film exposed by the contact hole; and performing a second cleaning for cleaning the semiconductor substrate. The second cleaning includes cleaning the semiconductor substrate with a cleaning solution which is a mixture of sulfuric acid (H₂SO₄), hydrogen peroxide (H₂O₂) and hydrogen fluoride (HF).

In accordance embodiments, it is possible to effectively remove residual products, residual photoresist and polymer generated after an etching process for forming contact holes or etching bottoms of the contacts holes. It is possible to secure a process margin for the contact profile in the cleaning process and to prevent an inferior contact profile and excessive film etching, thereby improving the semiconductor manufacturing production yield.

### DRAWINGS

Example FIG. 1 is a graph showing a dependency of an etching rate of an abnormal BPSG film on an NC₂ cleaning temperature in a related technique.

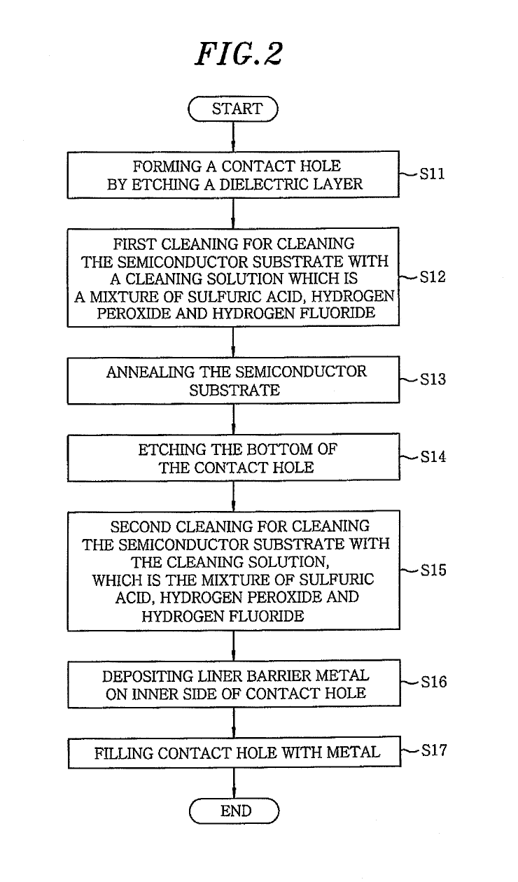

Example FIG. 2 is a flow chart of a method of manufacturing a semiconductor device according to embodiments.

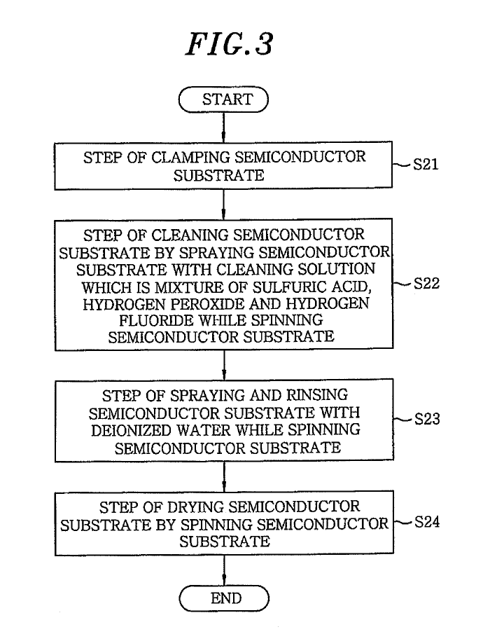

Example FIG. 3 is a flow chart of a method of cleaning a semiconductor device according to embodiments.

### DESCRIPTION

Example FIG. 2 is a flow chart of a semiconductor device manufacturing method in accordance with embodiments. As shown, the semiconductor device manufacturing method may include a step S11 of forming a contact hole by etching a dielectric layer, a first cleaning step S12 of cleaning a semiconductor substrate with a cleaning solution which is a mixture of sulfuric acid (H₂SO₄), hydrogen peroxide (H₂O₂) and hydrogen fluoride (HF), a step S13 of annealing the semiconductor substrate, a step S14 of etching the bottom of the contact hole, and a second cleaning step S15 of cleaning the semiconductor substrate with a cleaning solution which is a mixture of sulfuric acid (H₂SO₄), hydrogen peroxide (H₂O₂) and hydrogen fluoride (HF).

In the step S11 of forming a contact hole by etching a dielectric layer, the contact hole may be formed by etching the dielectric layer over a semiconductor substrate where a barrier film and the dielectric layer are sequentially formed by deposition over a lower metal pattern of a gate and a source/drain region. In this step, the barrier film may be a silicon nitride (SiN) film and the dielectric layer may be a boron phosphorus silicate glass (BPSG) film The dielectric layer may be planarized by a CMP (Chemical Mechanical Polishing) process.

To form the contact hole by etching the dielectric layer, a photo etching process (PEP) may be first performed to form a photoresist pattern for forming the contact hole. A photoresist may be applied over the BPSG film as the dielectric layer. Then, a reactive ion etching process using the photoresist pattern as a mask may be performed to form the contact hole in the BPSG film At this time, the barrier film may serve as a stop layer for etching of the BPSG film

After forming the contact hole, the first cleaning step S12 of cleaning the semiconductor substrate with a LIC-3 (low-temp inorganic chemical mixture-3) chemical, i.e., a cleaning solution which is a mixture of sulfuric acid (H₂SO₄), hydrogen peroxide (H₂O₂) and hydrogen fluoride (HF), may be performed to remove a residual product, residual photoresist and polymer. In this step, the mixture of sulfuric acid (H₂SO₄) and hydrogen peroxide (H₂O₂) may be used to effectively remove defects absorbed on a copper (Cu) surface by etching only a portion of metal under the condition of minimizing a metal attack. The hydrogen fluoride (HF) may be used to remove defects, which are difficult to be remove by being absorbed on a trench portion, by etching only a portion of the BPSG film, which is a kind of oxide.

The first cleaning step S12 may be the same as the method of cleaning the semiconductor device in accordance with embodiments. This may include a step S21 of clamping the semiconductor substrate, a step S22 of cleaning the semiconductor substrate by spraying the semiconductor substrate with the cleaning solution, which is the mixture of sulfuric acid (H₂SO₄), hydrogen peroxide (H₂O₂) and hydrogen fluoride (HF), while spinning the semiconductor substrate, a step S23 of spraying and rinsing the semiconductor substrate with deionized water while spinning the semiconductor substrate, and a step S24 of drying the semiconductor substrate by spinning the semiconductor substrate, as shown in example FIG. 3.

In the step S21 of clamping the semiconductor substrate, the semiconductor substrate may be clamped and fixed on a spin chuck, thereby allowing the semiconductor substrate to be cleaned using a single apparatus.

Once the semiconductor substrate is clamped on the spin chuck, the semiconductor substrate may be spun as the spin chuck is rotated. The rotating semiconductor substrate may be cleaned by spraying the semiconductor substrate with the cleaning solution which is the mixture of sulfuric acid (H₂SO₄), hydrogen peroxide (H₂O₂) and hydrogen fluoride (HF) (step S22). The mixture which may be used as the cleaning solution, for example, may include sulfuric acid (H₂SO₄) in a range from 5 to 12 wt %, hydrogen peroxide (H₂O₂) in a range from 3 to 8 wt % and hydrogen fluoride (HF) in a range from 100 to 300 ppm.

The step of cleaning the semiconductor substrate using the cleaning solution may be performed for a period of time during which residual photoresist and polymer are sufficiently removed and an effect on the BPSG film is minimized, for example, for 20 to 60 seconds. Then, the rotating semiconductor substrate may be rinsed for 40 to 60 seconds by spraying the semiconductor substrate with deionized water instead of the cleaning solution (step S23).

After the cleaning solution is removed from the semiconductor substrate by rinsing the semiconductor substrate, the semiconductor substrate may be dried by continuing to spin the semiconductor substrate using the spin chuck (step S24).

After completing the first cleaning step S12, the step S13 of annealing the semiconductor substrate may be performed. Then the step S14 of etching the bottom of the contact hole may be performed. In the step S14 of etching the bottom of the contact hole, the barrier film exposed by the contact hole may be etched to open the lower metal pattern. Specifically, the lower metal pattern, such as the gate and the source/drain region, may be opened by removing a region located on the bottom of the contact hole in the barrier film using a RIE (Reactive Ion Etching) process. Once the lower metal pattern is opened by etching the bottom of the contact hole, the second cleaning step S15 may be performed.

Similar to the first cleaning step S12, the second cleaning step S15 may include the step S21 of clamping the semiconductor substrate, the step S22 of cleaning the semiconductor substrate by spraying the semiconductor substrate with the cleaning solution, which is the mixture of sulfuric acid (H₂SO₄), hydrogen peroxide (H₂O₂) and hydrogen fluoride (HF), while spinning the semiconductor substrate, the step S23 of spraying and rinsing the semiconductor substrate with deionized water while spinning the semiconductor substrate, and the step S24 of drying the semiconductor substrate by spinning the semiconductor substrate, as shown in example FIG. 3. Explanation of these steps will not repeated since steps S21, S22, S23 and S24 have been described in detail in connection with the first cleaning step S12.

After completing the second cleaning step S15, liner barrier metal, e.g., Ti/TiN, may be formed over an inner side of the contact hole by deposition. The contact hole, having the liner barrier metal formed therein, may be filled with metal, e.g., tungsten (W), to complete the metal contact.

The method of cleaning the semiconductor device in accordance with embodiments may be a cleaning process performed after the etching process for forming the contact hole or after etching the bottom of the contact hole. The method involves cleaning the semiconductor substrate by using the cleaning solution which may be a mixture of sulfuric acid (H₂SO₄), hydrogen peroxide (H₂O₂) and hydrogen fluoride (HF). Here, explanation the cleaning process will not repeated since it is the same as the above-described first and second cleaning processes of steps S12 and S15.

With the above-described configuration, in the semiconductor device cleaning method in accordance with embodiments and the semiconductor device manufacturing method using the same, as configured above, it is possible to effectively remove residual products, residual photoresist and polymer, which are produced after etching the BPSG film for forming the contact hole or after etching the barrier film exposed by the contact hole, by using the LIC-3 chemical, i.e., the cleaning solution, which is the mixture of sulfuric acid (H₂SO₄), hydrogen peroxide (H₂O₂) and hydrogen fluoride (HF). In particular, the mixture of sulfuric acid (H₂SO₄), hydrogen peroxide (H₂O₂) effectively removes defects absorbed on a copper (Cu) surface by etching only a portion of the metal under conditions minimizing metal attack, and the hydrogen fluoride (HF) effectively removes defects, which are difficult to remove by being absorbed on a trench portion, by etching only a portion of the BPSG film which is a kind of oxide.

In addition, it is possible to clean the semiconductor substrate using a single apparatus, prevent an inferior contact profile and excessive film etching, which may occur in an abnormal BPSG film with an abnormal boron concentration in a related NC₂ cleaning process, by using the LIC-3 chemical, and secure a process margin for the contact profile in the cleaning process.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
etching one of a semiconductor substrate for forming a contact hole in the semiconductor substrate and the bottom of the contact hole on a semiconductor substrate; and
cleaning the semiconductor substrate with a cleaning solution wherein the cleaning solution includes a mixture of sulfuric acid, hydrogen peroxide and hydrogen fluoride.

2. The method of claim 1, wherein said cleaning solution includes sulfuric acid in a range from 5 to 12 wt %.

3. The method of claim 1, wherein said cleaning solution includes hydrogen peroxide in a range from 3 to 8 wt %.

4. The method of claim 1, wherein said cleaning solution includes hydrogen fluoride in a range from 100 to 300 ppm.

5. The method of claim 1, wherein said cleaning the semiconductor substrate includes:
clamping the semiconductor substrate on a spin chuck.

6. The method of claim 5, wherein said cleaning the semiconductor substrate includes:
cleaning the semiconductor substrate by spraying the semiconductor substrate with the cleaning solution while spinning the semiconductor substrate using the spin chuck.

7. The method of claim 6, wherein said cleaning the semiconductor substrate by spraying the semiconductor substrate with the cleaning solution is performed for 20 to 60 seconds.

8. The method of claim 7, wherein said cleaning the semiconductor substrate includes:
spraying and rinsing the semiconductor substrate with deionized water while spinning the semiconductor substrate; and
drying the semiconductor substrate by continuing to spin the semiconductor substrate.

9. A method comprising:
forming a contact hole on a semiconductor substrate where a barrier film and a dielectric layer are sequentially formed over a lower metal pattern by selectively etching a portion of the dielectric layer, thereby exposing a portion of the barrier film;
performing a first cleaning for cleaning the semiconductor substrate on which the contact hole is formed;
annealing the semiconductor substrate;
opening the lower metal pattern by etching the portion of the barrier film exposed by the contact hole; and
performing a second cleaning for cleaning the semiconductor substrate,
wherein said performing a first cleaning includes cleaning the semiconductor substrate with a cleaning solution which is a mixture of sulfuric acid, hydrogen peroxide and hydrogen fluoride.

10. The method of claim 9, wherein the cleaning solution includes sulfuric acid in a range from 5 to 12 wt %.

11. The method of claim 9, wherein the cleaning solution includes hydrogen peroxide in a range from 3 to 8 wt %.

12. The method of claim 9, wherein the cleaning solution includes hydrogen fluoride in a range from 100 to 300 ppm.

13. The method of claim 9, wherein said first cleaning includes:
clamping the semiconductor substrate on a spin chuck.

14. The method of claim 9, wherein said first cleaning includes:
cleaning the semiconductor substrate by spraying the semiconductor substrate with the cleaning solution while spinning the semiconductor substrate using the spin chuck.

15. The method of claim 14, wherein said cleaning the semiconductor substrate by spraying the semiconductor substrate with the cleaning solution is performed for 20 to 60 seconds.

16. The method of claim 9, wherein said first cleaning includes:
spraying and rinsing the semiconductor substrate with deionized water while spinning the semiconductor substrate; and
drying the semiconductor substrate by continuing to spin the semiconductor substrate.

17. A method comprising:
forming a contact hole on a semiconductor substrate where a barrier film and a dielectric layer are sequentially formed over a lower metal pattern, by selectively etching a portion of the dielectric layer, thereby exposing a portion of the barrier film;
performing a first cleaning for cleaning the semiconductor substrate on which the contact hole is formed;
annealing the semiconductor substrate;
opening the lower metal pattern by etching the portion of the barrier film exposed by the contact hole; and
performing a second cleaning for cleaning the semiconductor substrate,
wherein said second cleaning includes cleaning the semiconductor substrate with a cleaning solution which is a mixture of sulfuric acid, hydrogen peroxide and hydrogen fluoride.

18. The method according to claim 17, wherein the cleaning solution includes sulfuric acid in a range from 5 to 12 wt %, hydrogen peroxide in a range from 3 to 8 wt % and hydrogen fluoride in a range from 100 to 300 ppm.

19. The method of claim 17, wherein said second cleaning includes:
clamping the semiconductor substrate on a spin chuck;
cleaning the semiconductor substrate by spraying the semiconductor substrate with the cleaning solution while spinning the semiconductor substrate using the spin chuck;
spraying and rinsing the semiconductor substrate with deionized water while spinning the semiconductor substrate; and
drying the semiconductor substrate by continuing to spin the semiconductor substrate.

20. The method of claim 19, wherein said cleaning the semiconductor substrate by spraying the semiconductor substrate with the cleaning solution is performed for 20 to 60 seconds.
